(19) United States
(12) Patent Application Publication
(10) Pub. No.: US 2026/0223280 A1
(43) Pub. Date: Jul. 30, 2026

(54) HIGH CURRENT PRINTED ELECTRONICS CABLE HARNESS CONNECTION

(71) Applicant: JABIL INC., St. Petersburg, FL (US)

(72) Inventors: ED Collins, St. Petersburg, FL (US); Mark Sussman, St. Petersburg, FL (US)

(21) Appl. No.: 19/147,560

(22) PCT Filed: Jan. 10, 2024
(86) PCT No.: PCT/US2024/010988

§ 371 Date: Jul. 11, 2025

Related U.S. Application Data
(60) Provisional application No. 63/438,737, filed on Jan. 12, 2023.

(51) Int. Cl. H05K 1/02; H05K 1/09; H05K 1/11; H05K 1/14

(52) U.S. Cl. CPC H05K 1/0265; H05K 1/092; H05K 1/118; H05K 1/144; H05K 2201/10189

(57) ABSTRACT

An apparatus, system and method for a high current printed electronics cable assembly. The embodiments include; at least two flexible substrates; at least one conductive trace printed on at least one of a top face or a bottom face of each of the at least two flexible substrates; an insulator substantially covering the at least one conductive trace printed on each of the at least two flexible substrates, wherein an exposed end of the at least one conductive trace is uninsulated on at least one end of each of the at least two flexible substrates; a conductive foil placed over and electrically connected with the at least one conductive trace at the uninsulated exposed end; and a conductive element passing through the conductive foil to provide electrical connectivity to the at least one conductive trace on distinct ones of the at least two flexible substrates.

### CROSS-REFERENCE TO RELATED APPLICATIONS

The disclosure claims the benefit to U.S. patent application No. 63/438,737, filed Jan. 12, 2023, the disclosure of which is hereby incorporated by reference in its entirety.

### FIELD OF THE DISCLOSURE

The disclosure relates generally to printed electronics, and, more particularly, to an apparatus, system, and method of providing a high current printed electronics cable harness connection.

### BACKGROUND

It is often the case in numerous contexts that so-called standard cable harness wiring is used in applications where space is limited. For example, the cable harness wiring in an automobile may operate at 12 volts, 5 to 7 amps, and thus 60 to 80 watts, and may run through, around, and across various aspects of the vehicle. However, the available space in, for example, the engine compartment or passenger compartment of a vehicle through which those standard cable harness wires may run is typically very limited.

Various efforts have occurred to replace standard cable wiring with, for example, significantly thinner printed “wires”. However, making connections between such printed wiring is difficult, and the need to run such wiring around the aforementioned combined spaces necessitates that the substrates onto which the printed traces occur are flexible, making the connections of and endurance for these printed wires even more difficult.

Various solutions have been proposed to improve the connectivity between these so-called printed wires, particularly when flexible substrates are in use. By way of nonlimiting example, a conductive adhesive may be used to glue at least the edges, if not the entire substrates, together in layers, such that layers don't short together, but may be bent as required. However, the use of such conductive adhesives selectively may lead to a variety of other problems, such as undesired shorts when the wiring harness is kinked particularly tightly, by way of non-limiting example.

Therefore, the need exists for a high current printed electronics cable harness connection suitable for use with flexible substrates in tight quarters.

### SUMMARY OF THE DISCLOSURE

The embodiments provide an apparatus, system and method for a high current printed electronics cable assembly. The embodiments include: at least two flexible substrates; at least one conductive trace printed on at least one of a top face or a bottom face of each of the at least two flexible substrates; an insulator substantially covering the at least one conductive trace printed on each of the at least two flexible substrates, wherein an exposed end of the at least one conductive trace is uninsulated on at least one end of each of the at least two flexible substrates; a conductive foil placed over and electrically connected with the at least one conductive trace at the uninsulated exposed end; and a conductive element passing through the conductive foil to provide electrical connectivity to the at least one conductive trace on distinct ones of the at least two flexible substrates.

The embodiments provide an apparatus, system and method for a printed electronics assembly. The embodiments include: a flexible substrate; a first conductive trace printed on a first face of the substrate and a second conductive trace printed on a second face of the substrate, the second face being disposed opposite the first face of the substrate; an insulator covering at least a portion of the first conductive trace and the at least a portion of the second conductive trace, wherein at least another portion of the first conductive trace and at least another portion of the second conductive trace are exposed and uninsulated on an end of the flexible substrate; a conductive foil electrically coupled with the exposed portions of the first and second conductive traces; and a conductive element positioned through the conductive foil and configured to electrically couple the first conductive trace and the second conductive trace.

Thus, the embodiments provide a high current printed electronics cable harness connection suitable for use with flexible substrates in tight quarters.

### BRIEF DESCRIPTION OF THE DRAWINGS

This disclosure is illustrated by way of example and not by way of limitation in the accompanying figure(s). The figure(s) may, alone or in combination, illustrate one or more embodiments of the disclosure. Elements illustrated in the figure(s) are not necessarily drawn to scale. Reference labels may be repeated among the figures to indicate corresponding or analogous elements.

FIG. 1 illustrates aspects of an exemplary embodiment of the present invention;

FIG. 2 illustrates aspects of an exemplary embodiment of the present invention;

FIG. 3 illustrates aspects of the embodiments; and

FIG. 4 illustrates aspects of the embodiments.

### DETAILED DESCRIPTION

The figures and descriptions provided herein may have been simplified to illustrate aspects that are relevant for a clear understanding of the herein described devices, systems, and methods, while eliminating, for the purpose of clarity, other aspects that may be found in typical similar devices, systems, and methods. Those of ordinary skill may recognize that other elements and/or operations may be desirable and/or necessary to implement the devices, systems, and methods described herein. But because such elements and operations are well known in the art, and because they do not facilitate a better understanding of the present disclosure, a discussion of such elements and operations may not be provided herein. However, the present disclosure is deemed to inherently include all such elements, variations, and modifications to the described aspects that would be known to those of ordinary skill in the art.

The terminology used herein is for the purpose of describing particular example embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc., may be used herein to describe various elements, components, regions, layers and/or sections, these elements, components, regions, layers and/or sections should not be limited by these terms. These terms may be only used to distinguish one element, component, region, layer or section from another element, component, region, layer or section. That is, terms such as “first,” “second,” and other numerical terms, when used herein, do not imply a sequence or order unless clearly indicated by the context. Thus, a first element, component, region, layer or section discussed below could be termed a second element, component, region, layer or section without departing from the teachings of the exemplary embodiments.

The embodiments allow single or double-sided printed electronics (PE) strips, in some cases printed on flexible substrate(s), to be connected to one another in a manner similar to standard wire cabling, such as a high current cable/stranded cable wiring harness, for use in limited space environments. In one example, a substrate, such as a flexible substrate, is printed with conductive traces on the top and bottom side thereof. The conductive traces may be, by way of non-limiting example, printed of a silver ink. The conductive/insulative traces may be double printed/layer printed. The flexible substrate may be formed, by way of example, of plastic, such as of polycarbonate. Further, as will be appreciated by the skilled artisan, the printing of conductive traces on the top and bottom side of the flexible substrate may allow for double the conductivity of a single-sided print.

After printing, only the ends of the conductive traces may be left exposed for further conditioning or connection. Thereby, insulators/dielectrics may be used to shield or otherwise encapsulate the bulk of the trace, and thus the bulk of the flexible substrate, other than the end, which is left exposed for conditioning or connection. A conductive foil, such as copper by way of non-limiting example, may then be placed over the exposed surface area of the conductive trace at the end(s) of the substrate on both the top and bottom side of the flexible substrate. A hole may be placed through the conductive foil from the top side to the bottom side of the flexible substrate, such as by punching, pre-forming, or rivet-driving, such that the conductive trace on the top of the substrate and the conductive trace on the bottom of the substrate may include connectivity through the hole as between those traces on opposing faces, and/or such that traces from adjacent substrates may also be electrically connected via a conductive connector through the hole. Foil may be permanently associated with the conductive traces desired to be interconnected, at least so as to improve conductivity to that conductor resident within the hole, and hence to the connected traces on other substrates.

A conductive element through the hole, such as a metal rivet, may be placed/driven/formed through the hole to hold the foil and the substrate in place, while also acting as a conductive pass through from the top trace to the bottom trace through the conductive foil. Thereby, the conductive element through the hole may act as a via between printed traces (and thus electronics) on the top surface of a substrate and printed conductors on the bottom surface of the same substrate, or with conductors on an adjacent substrate physically and electrically connected to the conductive element.

Consequently, the use of vias is avoided in the embodiments, and conductivity between top and bottom surfaces of the substrate may instead be provided by the conductive metal element. The avoidance of the use of vias avoids concentration points for the connectivity between players that may undesirably raise resistance and thereby limit the performance of the disclosed “printed wires”, particularly when used in a larger harness of such wires.

In the disclosed embodiments, the foil may not only maintain and indeed improve the integrity of the printed traces, but may also significantly increase the amount of conductive surface area available for interconnection at the ends of the printed “wires”. Moreover, the placement of the metal element through the hole when the hole is through the conductive foil leads to less line loss.

Yet further, multiple substrates may have a metal rivet or like element, or multiple such elements, placed there through to allow for the stacking of several flexible substrate wires. In such a context, the metal rivet may serve both the retention function and the providing of a conductive path/connection through the metal rivet, as discussed throughout, but in this case, amongst the top and/or bottom traces of each of multiple stacked wires.

One or more clamps may be provided to hold the metal rivet/retention rod in place, and additionally to provide an electrical connection to an external circuit or system. For example, a clamp upon the rivet and/or associated otherwise with the foil connectively associated with the rivet may then clamp on the other end to one or more wires, or may connect on the other end to a printed circuit board (PCB) interface, by way of non-limiting example.

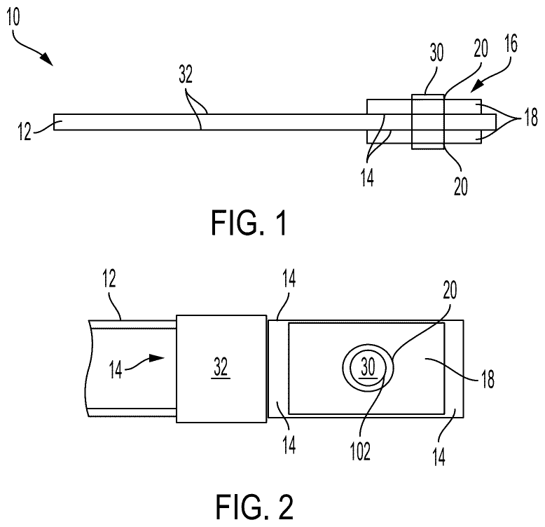

FIG. 1 illustrates a side view of the disclosed high current PE cable 10. As shown, a substrate 12, such as a flexible substrate, is provided. Upon the substrate, and, in some embodiments, on each side thereof, is printed one or more traces 14, which will serve as “wires” for a “cable”/“cable harness”. Such traces may be conductive, and/or dielectric. Such traces may be printed using masking or print-routing techniques, for example, such as, in accordance with a print template comprising a desired circuit outcome.

At an exposed end 16 of the “wire”, a conductive foil 18 is placed on the top and bottom of the substrate 12 to at least partially, and preferably, substantially or completely, cover the conductive trace 14 under the foil 18. The foil 18 may be formed, for example, of copper.

In some embodiments, a hole 20 may be placed through the upper and lower conductive foil 18 to accommodate a conductive element 30 therethrough, such as a metal rivet. In such embodiments, a conductive epoxy may be placed about the metal rivet to ensure an acceptable level of connectivity with the conductive traces under the conductive foil.

In other embodiments, the conductive element, such as the metallic rivet, may simply be driven through the upper layer of conductive foil, the substrate, and the lower layer of conductive foil. In such an embodiment, the metal rivet may make better contact with the conductive foil, and thus no conductive epoxy may be needed.

Substantially or completely about the flexible substrate, such as at least completely covering the aforementioned conductive traces on the top and bottom thereof, may be placed an insulator/dielectric 32. Placement of this insulator 32 may protect the flexible substrate, and hence the conductive traces, from damage, and may additionally prevent shorting as between the top and bottom conductive traces of adjacent flexible substrates in embodiments in which the substrates are stacked. Moreover, this insulative coating 32 prevents crosstalk between facing conductive traces of stacked substrates, even if a short does not occur, and additionally protects the printed surfaces of each substrate, at least because such surfaces typically are not flat or even, and if a conductive trace is unknowingly raised from the face of a substrate, it may be more likely to short or crosstalk with a facing conductive trace of an adjacent substrate.

FIG. 2 illustrates a top view of one of the embodiments. As shown, an insulator/dielectric 32 may be used to cover a substantial portion or the entirety of the conductive trace 14 and/or the substrate 12. The conductive foil 18 on the face of the substrate 12 shown may substantially cover the conductive trace 14. The metal rivet/conductive element 30 may be placed through the conductive foil 18 on the top and bottom phases of the substrate 12, such as in order to both lock in place the substrate 12, the foil 18, and any adjacent substrates, and to also provide connectivity as between the foil 18 and the conductive trace 14, and a point at which a clamped or clipped input may be provided to the foil 18 and hence to the conductive trace 14. Of note, the driving of the rivet 30 through the top and bottom layers of conductive foil 18, and through the substrate 12, to form hole 20 may lower connection resistance and help with oxidation issues. Moreover, conductive epoxy 102 may be provided to improve the connection of rivet 30 in hole 20.

The rivet 30 may include masking, so as to target conductivity to certain traces. This masking may be printed to the rivet 30. Similarly, the diameter of the rivet 30 may vary, such as to provide connectivity only to targeted traces, and/or to provide targeted structural support.

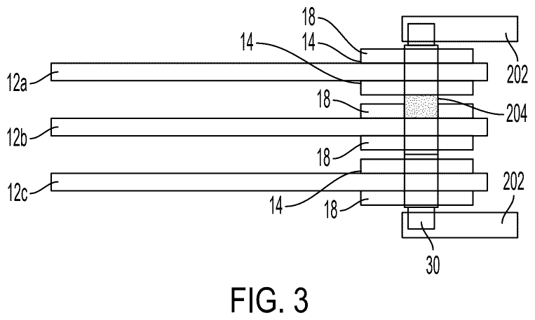

FIG. 3 shows an embodiment in which three substrates 12a, 12b, 12c are stacked, one atop the other, with a conductive rod/rivet 30 placed through the foil layers 18 of all three substrates 12a, 12b, 12c, and consequently not only the foil layers 18 but also the top and bottom conductive traces 14. Also illustrated in FIG. 3 are a plurality of conductive clamps 202 placed upon the conductive metal rivet 30, in order to provide an electrical interface to and through the multiple stacked substrates 12a, 12b, 12c.

Of note in the embodiment of FIG. 3, it will be appreciated that any number of flexible substrates 12a, 12b, 12c, . . . may be stacked in the manner shown. Moreover, the metal rivet/rod 30 may include areas that are “blanked out”, such as having placed thereon an insulator/dielectric 204, so as to prevent conduction from the metal rivet/rod 30 to the conductive foil 18 and traces 14 on the substrate where the metal rivet/rod 30 is “blanked out”. Likewise, conductive clamps 202 may be provided at various points along the metal rivet/rod 30, such as wherein portions of the metal rivet/rod 30 are conductive or not conductive. That is, certain substrates may be “blanked out” by making the entirety of the metal rivet/rod 30 nonconducting where the metal rivet/rod 30 passes through that substrate. In such an embodiment, conductive clamps 202 may be provided as an interface above and below the “blanked out” portion, with a second interface provided on the corresponding side of the “blanked out” portion, such that a circuit may be completed on each side of the “blanked out” portion.

As such, a single metal rod may provide different signaling and/or like electrical connections to different substrates through which the rod passes. As discussed above, certain portions of the rod may be “blanked out”, certain portions of the rod may be made non-conductive in their entirety, and as such, interfacing only to select conductive traces may be provided by a single metal rivet.

In a similar embodiment, conductive or non-conductive spacers, i.e., variations in the diameter of the metal rivet, may provide the aforementioned selective interfacing. Similarly, such as in embodiments wherein, the rivet holes are pre-punched through the substrate and the conductive foil, certain ones of the holes may be circumferentially coated or clamped with a dielectric or insulator, such that when the metal rivet passes therethrough, no conduction from the metal rivet to that substrate occurs, and instead the metal rivet serves only to provide the spacing for that flexible substrate.

Likewise, if the diameter of the rivet is to be varied, and/or if insulation is selectively provided along the metal rivet, conductive epoxy may be needed only at those strips to which the interface is to make an electrical connection. In an alternative embodiment, selective insulation may be provided over the conductive traces, such that signaling and/or electrical connections may occur between conductive traces on adjacent faces of adjacent flexible substrates. Moreover, the embodiments allow for significant variations unknown in the prior art that may improve performance between adjacent strips. For example, as printed electronic strips, such as may be formed of silver ink, suffer inherently more loss than known copper wire, under thickness of traces or variability in conductive trace thickness may be cured by thicker/wider conductive traces in the embodiments, since each trace is covered by an insulator to protect it from an adjacent trace on an adjacent face of an adjacent strip.

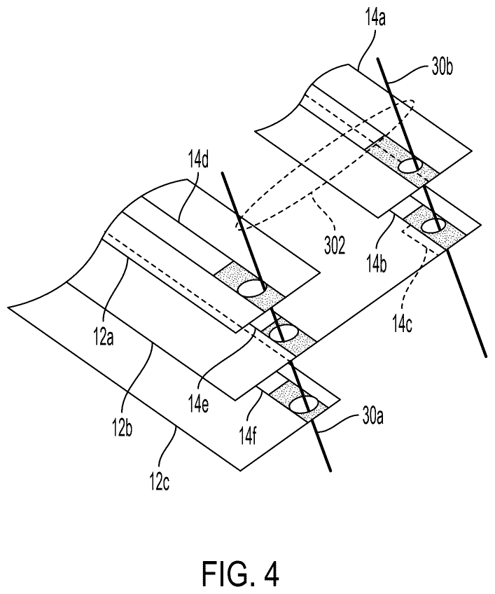

FIG. 4 illustrates the use of multiple rivets 30a, 30b across several substrates 12a, 12b, 12c each having multiple terminating conductive traces 14a, 14b, 14c, 14d, 14e, 14f . . . at the edge thereof, wherein such substrates are stacked upon one another. The skilled artisan will appreciate that, in such an embodiment, rather than one substrate having multiple terminating conductive traces at the edge thereof, multiple substrates may also be placed in parallel, i.e., next to one another.

In the illustration, multiple rivets may be placed adjacent to each other, each passing through multiple top and/or bottom traces of each substrate throughout the multiple stacked substrates. In the illustration, the metal rivets placed through the stacked substrates may be individualized single rivets 30a, 30b, or may be part of a set of rivets connected to one another by an insulator 302, such as to maintain distance between the rivets. In any such case, the multiple rivets may provide different access to different traces across different ones of the substrates. By way of example, individual rivets may also have “blanked out” sections, such that individual substrate traces do not receive electron flow from incoming electrons to an individual rivet, as discussed above with respect to FIG. 3.

In such embodiments, modifications might need to be made to the thickness, resistance, conductivity, or other electrical properties or electromechanical properties of individual traces when placed in parallel to be held by the rivet system. For example, some conductive traces may receive the insulative cover 32 discussed around, and such insulative cover 32 may partially or completely insulate the conductive traces, and other traces may not receive full insulative cover.

As will be appreciated by the skilled artists, certain electrical or electromechanical properties, such as increased connectivity, sufficient conductivity, decreased stray resistance, mechanical integrity, and the like may dictate modifications to the illustrated metal rivets. For example, the length or composition of the rivets may vary, as may the cross-sectional shape. For example, cylindrical rivets may work best for certain embodiments, while rectangular or triangular rivets may work best for other operational environments. Likewise, the thickness, length, or makeup of the conductive foil may also vary based on the electrical or electromechanical needs of particular embodiments. Yet further, the electrical treatment of conductive traces may not be uniform on any given substrate. By way of a nonlimiting example, a conductive trace on the bottom of a substrate may be “blanked out”, or may not receive a conductive foil cover 18, whereas a top trace on the same substrate may receive different electrical or electromechanical treatment, based on the particular needs in a given embodiment.

Of additional note, it will be appreciated in light of the disclosed embodiments that the rivets 30 may be used to provide “snap-in” traces where conductivity/connectivity is desired. That is, rather than printing conductive junctions in traces of a print template, trace-gaps may be provided and, when connectivity between traces aside the trace-gap is desired, a rivet may be snapped/punched into place to provide the requisite connectivity as between the previously unconnected adjacent traces. This may be the case for one side of a substrate, both sides of a substrate, or adjacent substrates, rather than rivets being used only at trace-ends and/or exposed end-portions of substrates.

Moreover, the disclosed embodiments may thus provide great variability in the size, shape and number of substrates used in a given context. Indeed, snap-in connectivity may enable stock substrates with pre-printed templates to be variably used in a variety of contexts. A significant consideration in such exemplary embodiments would be the resistance of the traces in light of the power requirements. By way of non-limiting example, a 12V, high current embodiment (such as for use in a car) may necessitate the use of traces of a certain makeup (such as silver ink) and a certain trace thickness for ones of the contexts herein, which may be distinct from a 120V, lower current context.

In the foregoing Detailed Description, it can be seen that various features are grouped together in a single embodiment for the purpose of clarity and brevity of the disclosure. This method of disclosure is not to be interpreted as reflecting an intention that the embodiments require more features than are expressly recited herein. Rather, the disclosure is to encompass all variations and modifications to the disclosed embodiments that would be understood to the skilled artisan in light of the disclosure.

What is claimed is:

1. A high current printed electronics cable assembly, comprising:
at least two flexible substrates;
at least one conductive trace printed on at least one of a top face or a bottom face of each of the at least two flexible substrates;
an insulator substantially covering the at least one conductive trace printed on each of the at least two flexible substrates, wherein an exposed end of the at least one conductive trace is uninsulated on at least one end of each of the at least two flexible substrates;
a conductive foil placed over and electrically connected with the at least one conductive trace at the uninsulated exposed end; and
a conductive element passing through the conductive foil to provide electrical connectivity to the at least one conductive trace on distinct ones of the at least two flexible substrates.

2. The assembly of claim 1, wherein each of the at least two flexible substrates comprise plastic.

3. The assembly of claim 1, wherein the at least one conductive trace comprise silver ink.

4. The assembly of claim 1, wherein the insulator is a printed dielectric.

5. The assembly of claim 1, wherein the conductive foil comprises copper.

6. The assembly of claim 1, wherein the conductive element comprises a metal rivet.

7. The assembly of claim 1, wherein the conductive element passes through a pre-punched hole in each of the flexible substrates.

8. The assembly of claim 7, wherein the pre-punched hole is coated with conductive adhesive to improve the electrical connectivity between the conductive element and the conductive foil.

9. The assembly of claim 1, wherein the conductive element is punched through from atop one of the flexible substrates through an adjacent one of the flexible substrates.

10. The assembly of claim 1, further comprising a connective clamp electrically and physically associated with ends of the conductive element.

11. The assembly of claim 10, wherein the connective clamp is electrically communicative with a printed circuit board.

12. The assembly of claim 1, wherein the flexible substrates are stacked one atop the other.

13. The assembly of claim 1, wherein portions of the conductive element are insulated from ones of the conductive traces in a stack of the at least two flexible substrates.

14. The assembly of claim 1, wherein the at least two flexible substrates have multiple ones of the conductive elements passing therethrough laterally adjacent to one another.

15. The assembly of claim 14, wherein the conductive elements are held in place relative to one another by insulative spacers.

16. A printed electronics assembly, comprising:
a flexible substrate;
a first conductive trace printed on a first face of the substrate and a second conductive trace printed on a second face of the substrate, the second face being disposed opposite the first face of the substrate;
an insulator covering at least a portion of the first conductive trace and the at least a portion of the second conductive trace, wherein at least another portion of the first conductive trace and at least another portion of the second conductive trace are exposed and uninsulated on an end of the flexible substrate;
a conductive foil electrically coupled with the exposed portions of the first and second conductive traces; and
a conductive element positioned through the conductive foil and configured to electrically couple the first conductive trace and the second conductive trace.

17. The assembly of claim 16, wherein the conductive element passes through a hole in the flexible substrate.

18. The assembly of claim 16, further comprising:
the flexible substrate comprising a first substrate;
a second flexible substrate stacked on the first flexible substrate;
a third conductive trace printed on a face of the second flexible substrate and a fourth conductive trace printed on an opposing face of the second flexible substrate;
a second insulator covering at least a portion of the third conductive trace and the at least a portion of the fourth conductive trace, wherein at least another portion of the third conductive trace and at least another portion of the fourth conductive trace are exposed and uninsulated on an end of the second flexible substrate; and
a second conductive foil electrically coupled with the exposed portions of the third and fourth conductive traces.

19. The assembly of claim 18, wherein the conductive element is positioned through the first flexible substrate and the second flexible substrate to electrically couple one or a combination of the first conductive trace, the second conductive trace, the third conductive trace, and the fourth conductive trace to one another.

20. The assembly of claim 19, wherein one or more insulators are disposed along the conductive element to prevent a respective one of the first conductive trace, the second conductive trace, the third conductive trace, or the fourth conductive trace from being electrically coupled to the conductive element.
